(19) United States
(12) Patent Application Publication
(10) Pub. No.: US 2025/0277880 A1
(43) Pub. Date: Sep. 4, 2025

(54) RECEIVING DEVICE WITH AN INTRACARDIAC RECEIVING ANTENNA FOR MAGNETIC RESONANCE IMAGING OR SPECTROSCOPY

(71) Applicants: UNIVERSITE DE BORDEAUX, BORDEAUX (FR); FONDATION BORDEAUX UNIVERSITÉ, BORDEAUX (FR); UNIVERSITE PARIS-SACLAY, GIF-SUR-YVETTE (FR); CENTRE NATIONAL DE LA RECHERCHE SCIENTIFIQUE, PARIS (FR); INSTITUT NATIONAL DE LA SANTE ET DE LA RECHERCHE MEDICALE, PARIS (FR); COMMISSARIAT A L’ENERGIE ATOMIQUE ET AUX ENERGIES ALTERNATIVES, PARIS (FR)

(72) Inventors: Bruno QUESSON, CESTAS (FR); Marie POIRIER-QUINOT, MASSY (FR); Sina MARHABAIE, EVRY-COURCOURONNES (FR)

(21) Appl. No.: 18/858,675

(22) PCT Filed: Apr. 21, 2023
(86) PCT No.: PCT/EP2023/060483

§ 371 Date: Oct. 21, 2024

(30) Foreign Application Priority Data
Apr. 22, 2022 (FR) 2203778

(51) Int. Cl. G01R 33/36; G01R 33/28; G01R 33/34

(52) U.S. Cl. CPC G01R 33/3657; G01R 33/288; G01R 33/34084

(57) ABSTRACT

A device for receiving radio frequency signals for a magnetic resonance imaging/spectroscopy system including an intracardiac receiving resonant loop and a switch capable of being alternately in an open state such that the frequency of the receiving antenna is tuned to an operating frequency of the magnetic resonance imaging system, and in a closed state such that the frequency of the receiving resonant loop is detuned, the receiving device including a first transmission line having a conductor with a distal end electrically connected to the receiving resonant loop and a proximal end electrically connected to the switch such that the switch is intended to be located outside the human body when the receiving resonant loop is located inside a patient's heart.

### FIELD OF THE INVENTION

The invention relates to the field of intracavitary, in particular intracardiac, magnetic resonance imaging/spectroscopy (MRI/MRS).

MRI/MRS systems conventionally comprise a main magnet intended to generate a uniform permanent magnetic field B₀, three gradient coils, an external transmission antenna intended to generate radio frequency (RF) excitation signals to flip a magnetization of the tissues of the patient uniformly in space.

In the context of intracavitary MRI, an antenna for receiving RF signals resulting from the excitation of an organ of interest by the RF excitation signals is intended to be brought into contact with the organ of interest, the heart for intracardiac imaging, either vascularly through a natural orifice or percutaneously. The interest of the intracavitary antenna is to make it possible to obtain optimal spatial selectivity related to the geometry of the receiving antenna (shape, dimension) and its location as well as improved sensitivity with respect to extracorporeal antennas and consequently to increase the signal to noise ratio. Spatial selectivity makes it possible to limit the field of view of the images to be acquired and to reduce their acquisition time. The signal to noise ratio gain makes it possible to generate images of good quality and/or with better spatial resolution compared to extracorporeal antennas, which is fundamental for imaging the walls of the heart, notably atria, the thickness of which is comprised between 2 mm and 5 mm.

The receiving antenna comprises a receiving loop, i.e. a receiving coil, and capacitors for frequency tuning and matching the characteristic impedance of the transmission line (typically 50 Ohms). The receiving antenna is connected to a receiver of the MRI device by a transmission line integrated within a sheath and intended to convey the radio frequency signals received by the antenna to the receiver so that the latter records these signals.

The receiving antenna is a resonant circuit of R, L, C type, the resonance frequency fR of which must be equal to the Larmor frequency f₀ of the MRI system, the value of which depends on the magnetic induction B₀ of the MRI (f₀=γBo/2π). γ is the gyromagnetic ratio of the nucleus of interest, which is very frequently hydrogen, 1H. For example, for hydrogen γ=42.57 MHz/Tesla, which gives a resonance frequency of around 64 MHz for a magnetic field of 1.5 Tesla.

Since the transmitting and receiving antennas operate at the same frequency f₀, it is essential that the receiving antenna is tuned to the frequency f₀ during the phase of receiving the RF signals transmitted by the organ of interest and that it is frequency detuned during the transmission phase. If this is not the case, a high intensity current may be induced in the receiving antenna during the transmission phase, which leads to the following effects:
creation of heating points capable of burning the patient, or capable of inducing coagulation necrosis of the tissues in contact with the receiving antenna, which causes insecurity problems for the patient,
creation of an inhomogeneity of the magnetic field B₁ generated by the transmission antenna near the receiving antenna modifying the characteristics of the acquisition technique (modification of contrasts) and deteriorating the quality of the MRI images,
potential deterioration of the MRI detection device (hardware breakage).

This switching system must make it possible to switch quickly and dynamically between the two states during the entire acquisition time of the MRI sequence. For this purpose, active decoupling equipment must be used and ensure sufficient electrical isolation (attenuation difference between the coupled and decoupled state) at the frequency f₀ to avoid the aforementioned problems.

### PRIOR ART

Switching between the tuned state and the detuned state of the receiving antenna is performed dynamically by an active decoupling equipment which is capable of temporarily modifying the frequency response of the receiving antenna.

The active decoupling equipment conventionally comprises a PIN diode that is supplied with direct current during the transmission phase so that the PIN diode is ON and the frequency of the receiving antenna is detuned. The PIN diode is no longer supplied with direct current during the receiving phase such that the frequency of the receiving antenna is tuned.

The article “Intracardiac MR imaging (ICMRI) guiding-sheath with amplified expandable-tip imaging and MR tracking for navigation and arrhythmia ablation monitoring: Swine testing at 1.5 and 3T”; Schmidt et al, Magnetic Resonance in Medicine, discloses a receiving device comprising intracavitary decoupling equipment.

However, it may prove to be dangerous for the patient to electrically supply intracavitary equipment, in particular intracardiac equipment, with a direct current of several hundred milliamps. Indeed, such a direct current is capable of causing cardiac arrest if the components of the receiving antenna come into contact with the myocardium. Furthermore, this solution poses problems of bulk.

One aim of the invention is to limit at least one of the aforementioned drawbacks.

To this end, the invention relates to a device for receiving radio frequency signals for a magnetic resonance imaging system comprising an intracardiac receiving resonant antenna and a switch capable of being alternately in an open state when supplied with a direct current having a first intensity such that the receiving antenna is tuned to an operating frequency of the magnetic resonance imaging system and in a closed state when supplied by a direct current having a second intensity such that the frequency of the receiving antenna is detuned, the receiving antenna being further intended to be connected to a receiver intended to receive the radio frequency signals received by the receiving resonant loop, i.e. the receiving resonant antenna, when the switch is in the open state, the receiving device comprising a first transmission line having a conductor having a distal end electrically connected to the receiving resonant antenna and a proximal end electrically connected to the switch such that the switch is intended to be located outside the human body while the receiving antenna is located inside a patient's heart.

In one embodiment, the device comprises, further to the first transmission line, a second transmission line having a conductor comprising a distal end electrically connected to the receiving antenna and a proximal end intended to be electrically connected to the receiver and intended to be connected to the receiver to transmit to it the radio frequency signals received by the receiving antenna.

Advantageously, the receiver is intended to be electrically connected to the receiving transmission line so as to receive radio frequency signals received by the receiving antenna via the receiving transmission line without passing through the decoupling transmission line.

Advantageously, the receiving antenna comprises a tuning capacitor and a matching capacitor mounted in series and connected by a ground point, the tuning capacitor electrically connecting the conductor of the second transmission line to the ground point.

In another embodiment, the proximal end of the conductor of the first transmission line is intended to be connected to the receiver to transmit to it the radio frequency signals received by the receiving antenna.

Advantageously, the receiving device comprises an electrical circuit having a negative resistance mounted in series with the switch.

Advantageously, the matching capacitor electrically connects the ground point to the conductor of the first transmission line.

Advantageously, the electrical circuit having the negative resistance connects the switch to ground.

Advantageously, the electrical circuit having the negative resistance is intended to be located outside the human body when the receiving antenna is located inside a patient's heart.

In a particular embodiment, the receiving device comprises a sheath receiving the first transmission line, the sheath comprising a proximal end mechanically connected to the switch and a distal end capable of receiving the receiving resonant antenna.

Advantageously, the sheath has a diameter less than or equal to 2 mm. The invention also relates to a magnetic resonance imaging or spectroscopy system comprising a receiving device according to the invention, the system comprising a magnetic resonance imaging or spectroscopy device, the magnetic resonance imaging or spectroscopy device comprising a main magnet intended to generate a static magnetic field, a gradient generator comprising gradient coils and a transmitting antenna intended to transmit radio frequency signals.

Advantageously, the magnetic resonance imaging or spectroscopy device comprises the receiver.

### BRIEF DESCRIPTION OF THE FIGURES

Other characteristics and advantages of the invention will become clearer upon reading the following detailed description, in reference to the appended figures, that illustrate:

FIG. 1: a schematic representation of an MRI/MRS system having a receiving device according to a first embodiment,

FIG. 2: a representation of the electrical diagram of the receiving device according to the first embodiment,

FIG. 3: a representation of the electrical diagram of the receiving device according to a second embodiment,

FIG. 4: a representation of the electrical diagram of the receiving device according to a third embodiment,

FIG. 5: a representation of the electrical diagram of the receiving device according to an alternative of the third embodiment,

FIG. 6: a schematic representation of an MRI/MRS system having a receiving device according to the third embodiment.

### DESCRIPTION OF THE INVENTION

The invention relates to a receiving device of a magnetic resonance imaging/spectroscopy system or MRI/MRS intended to operate at an operating frequency f₀.

### GENERAL DESCRIPTION OF THE MRI/MRS SYSTEM

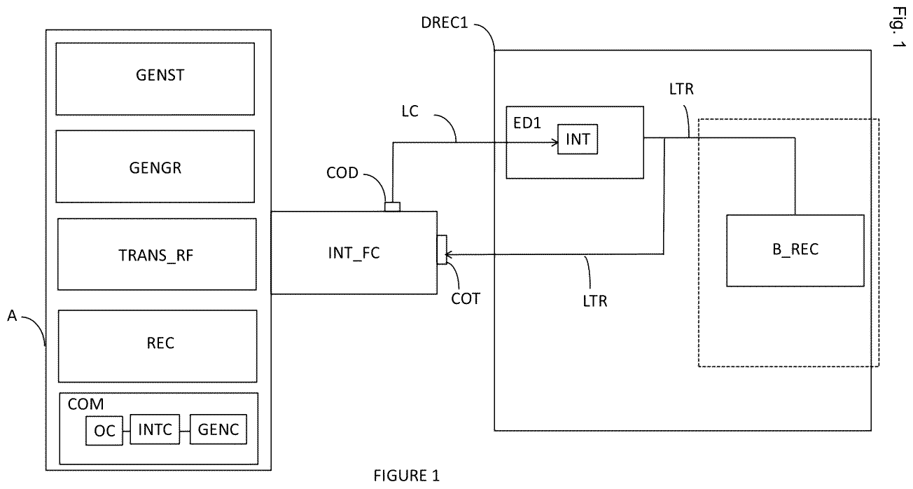

An MRI/MRS system comprising a receiving device DREC1 of which a first embodiment of the invention is shown in FIG. 1. Of course, the MRI/MRS system could in an alternative comprise a receiving device according to any one of the embodiments and alternatives described in the present patent application.

The MRI/MRS system comprises an MRI/MRS device, A, comprising a main magnet GENST intended to generate a static magnetic field B₀, a gradient generator GENGR comprising gradient coils, a transmission antenna TRANS_RF intended to transmit radio frequency (RF) signals. The MRI/MRS system, A, comprises a receiving device DREC1 comprising a receiving antenna B_REC intended to receive radio frequency signals resulting from the excitation of an area of interest of a patient by the transmitting antenna TRANS_RF. The MRI/MRS device, A, comprises a receiver REC intended to receive the signals received by the receiving device DREC1 and to process them to generate images/spectra.

The receiving device DREC1 is electrically connected to the MRI device, A, by an interface INT_FC of the MRI/MRS device comprising connectors COD and COT.

The operating frequency or Larmor frequency f₀ is proportional to the static magnetic field B₀ as specified above.

The most common magnetic fields B₀ in clinical MRI/MRS are 1.5 Tesla, 3.0 Tesla or 7.0 Tesla but the invention applies to other magnetic fields B₀, for example, between 0.1 Tesla and 11 Tesla.

The receiving antenna B_REC is an intracardiac resonant antenna.

An intracardiac receiving resonant antenna B_REC means a receiving antenna of the RLC circuit type intended to be inserted into a cavity of the heart of a patient whose body is delimited in dotted lines in FIG. 1 so as to image an area of the heart by magnetic resonance.

The receiving device DREC1 comprises active decoupling equipment ED1 electrically connected to the intracardiac receiving antenna B_REC. The decoupling equipment ED1 comprises a decoupling switch INT, which will be described more precisely below, capable of being alternately in an open state when it is supplied by a direct current of a first intensity so that the receiving antenna resonates at the frequency f₀ and in a closed state when it is supplied by a direct current of a second intensity so that the antenna no longer resonates at the frequency f₀. For example, the decoupling switch is capable in the open state when it is not supplied with current and in the closed state when it is supplied with a second direct current.

For example, the first current is null and the second direct current is non-null.

It is said that when the decoupling switch is in the open state, the receiving antenna is tuned to the frequency f₀ and when the switch is in the closed state, the frequency of the antenna is detuned and is no longer matched in impedance with the transmission line at the frequency f₀.

The MRI/MRS device, A, comprises a control device COM capable of electrically controlling the switch by supplying it by means of a first intensity of direct current and a second intensity of direct current so as to make it go from the open state to the closed state and vice versa and to maintain it in the desired state for a desired duration. The control device COM advantageously comprises a current generator GENC capable of delivering the second current and electrically connected to the switch INT of the decoupling equipment ED1 via a conductor or transmission line LC connected to the interface INT_FC via the first connector COD, and a control switch INTC controlled by a control member OC of the control device COM so that alternately the current generator supplies the switch INT of the decoupling equipment ED1 by means of the second current and it no longer supplies the switch INT of the decoupling equipment ED1 with current.

Advantageously, the control device COM, notably the control member OC, is capable of controlling the RF transmission antenna TRANS_RF and the switch INT of the decoupling equipment ED1 in a synchronized manner such that the frequency of the receiving antenna B_REC is detuned, in the transmission phase, when the transmission antenna TRANS_RF transmits RF signals and tuned to the frequency f₀, in the receiving phase, when the transmission antenna TRANS_RF does not transmit RF signals.

The receiving antenna B_REC is intended to be electrically connected to the receiver REC of the MRI/MRS system such that the receiver REC receives the radio frequency signals received by the receiving antenna B_REC during the receiving phase.

For this purpose, the receiving device DREC1 comprises a transmission line, so-called receiving, LTR, of which a first conductor comprises a first end connected to the receiving antenna B_REC and a second end connected to a transmission connector COT of the interface INT_FC electrically connected to the receiver REC of the MRI system so that the receiving transmission line LTR transmits, to the receiver REC, the RF signals received by the receiving antenna B_REC when the switch INT is open, i.e. during the receiving phase.

The transmission line LTR is for example a coaxial cable, a two-wire line or a twisted pair.

In a non-limiting embodiment, the first conductor of the receiving transmission line LTR is mounted in series with the switch INT as we will see later.

According to the invention, the switch INT of the decoupling equipment ED is intended to be located outside the patient's body (delimited by dotted lines in FIG. 1) while the receiving antenna is located inside the patient's heart.

This solution makes it possible to avoid the risks linked to disposing the switch in the human body. In particular, it makes it possible to avoid having to convey a direct current in the human body to control the passage of the switch INT from the open state to the closed state, which limits the risks to the health of the patient. Furthermore, this solution makes it possible to limit the bulk of the part of the receiving device DREC1 intended to be inserted into the human body, which is fundamental for intracardiac imaging requiring the passage of this part into vessels, the diameter of which is of the order of 2 mm, to reach the part of the heart to be imaged. Furthermore, this solution is simple to implement and economical (it does not require the use of miniature and non-magnetic active components to produce the decoupling equipment).

### First Embodiment

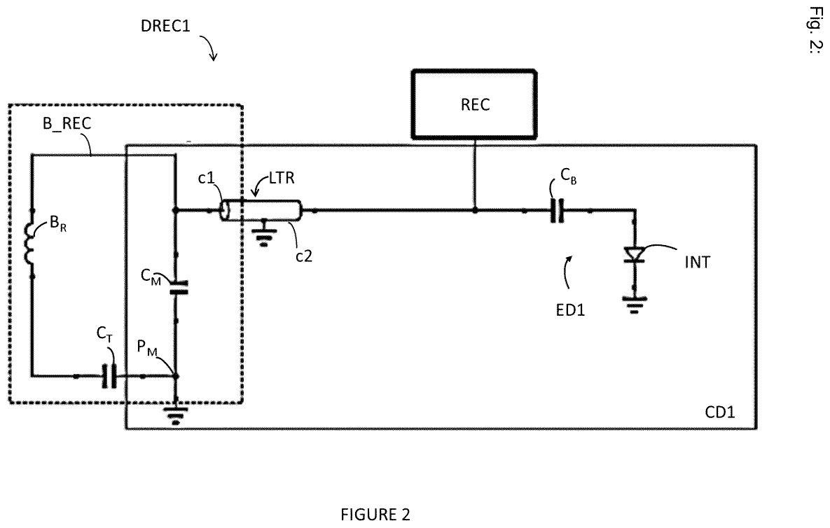

FIG. 2 shows the electrical diagram of the receiving device DREC1 of FIG. 1 electrically connected to the receiver REC.

The equivalent electrical diagram of the receiving resonant antenna B_REC is a looped electrical circuit comprising a receiving coil B_{R} connected in series with a matching capacitor C_{M} and with a tuning capacitor C_{T}. The tuning capacitor C_{T} and the matching capacitor C_{M} are connected to each other by a ground point P_{M} electrically connected to the second conductor c2 of the transmission line which is electrically connected to ground. The tuning capacitor C_{T} electrically connects the ground point P_{M} to the receiving coil B_REC.

The matching capacitor C_{M} electrically connects the distal end of the first conductor c1 of the receiving transmission line LTR to the ground point P_{M}. The first conductor c1 is, for example, a core of a coaxial cable.

A second conductor c2 of the receiving transmission line LTR is electrically connected to ground. The second conductor c2 is, for example, the shield or “braid” of the coaxial cable.

The proximal end of the receiving transmission line LTR is electrically connected to the receiver REC and the decoupling equipment ED1. The receiving transmission line LTR therefore has a function of transmitting radio frequency signals received by the receiving antenna B_REC to the receiver REC and a decoupling transmission line function.

The decoupling equipment ED1 comprises the switch INT which is a PIN diode in the non-limiting example of FIG. 2. In an alternative, the switch is another type of controllable switch, for example a mechanical switch or a relay, for example a reed switch.

The decoupling equipment ED1 also comprises a direct current blocking capacitor C_{B} mounted in series with the switch INT and with the receiving transmission line LTR, more particularly with the first conductor c1 of the receiving transmission line LTR.

The blocking capacitor C_{B} is configured to block the DC component of the current. It therefore prevents the control direct current of the switch INT from reaching the receiving antenna B_REC and thus damaging it and avoiding the harmful effects on the patient mentioned above in the document. The blocking capacitor C_{B} must have a sufficiently high capacitance and have a sufficiently low impedance to not prevent the transmission of the RF signal. At 64 MHz for example, a value greater than or equal to 1 nF.

The distal end of the first conductor c1 of the receiving transmission line LTR is connected to the receiving antenna B_REC in a first terminal of the matching capacitor C_{M}, the second terminal of the matching capacitor C_{M} being connected to the ground point P_{M}.

The capacitance of the matching capacitor C_{M} is defined in such a way that the equivalent impedance of the receiving antenna B_REC is seen, by the transmission line, as an impedance equal to the characteristic impedance of the transmission line. The matching capacitor C_{M} then has an impedance matching function between the receiving antenna B_REC and the transmission line LTR.

Advantageously, the capacitance of the matching capacitor C_{M} is defined in such a way that the receiving antenna is seen as an impedance of 50 Ohms by the transmission line. This makes it possible to use a transmission line, for example, a 50 Ohms coaxial cable.

The matching capacitor C_{M}, the receiving transmission line LTR and the decoupling equipment ED1 (blocking capacitor C_{B} and switch INT) form a resonant decoupling circuit surrounded by a full line frame in FIG. 2, the function of which is to ensure the coupling between the receiving antenna B_REC and the MRI device A in the receiving phase and to decouple the receiving antenna B_REC and the MRI device A in the transmission phase.

The decoupling circuit is configured to resonate at the frequency f₀. The resonance frequency depends on the values of the elements (capacitance, inductance depending on the length of the transmission line LTR or LTD) of the elements forming this circuit.

The receiving transmission line LTR therefore has a dual function of transmission of radio frequency signals during the receiving phase and of transmission line equivalent to an inductance during the transmission phase.

When the switch INT is closed (transmission phase), i.e. when it is supplied with current, the switch INT connects the blocking capacitor to ground. The equivalent diagram of the decoupling circuit is the matching capacitor C_{M} in series with the receiving transmission line LTR in series with the blocking capacitor C_{B} and with the switch INT.

To have the decoupling function, the receiving transmission line LTR has an inductance function. The length of the receiving transmission line LTR is defined in such a way that the resonance frequency of the decoupling circuit CD1 is equal to the frequency f₀. This length is calculated approximately, and the precise length is then determined experimentally so as to obtain the desired resonance frequency.

The length of the receiving transmission line LTR is also defined so that the decoupling equipment and more particularly the switch INT is located outside the human body when the receiving antenna B_REC is located in the heart.

It is typically greater than or equal to 30 cm or 40 cm when the receiving antenna is intended to be inserted into the body through a jugular access and greater than or equal to 80 cm when the receiving antenna is intended to be inserted into the body through an access via the groin.

In transmission, the decoupling circuit CD1 has a high impedance at the resonance frequency f₀, which means that it behaves as an open circuit. The receiving antenna B_REC is then assimilable to the receiving coil B_{R} mounted in series with the tuning capacitor C_{T}. This latter circuit is frequency detuned (i.e. it no longer resonates at the frequency f₀). It resonates, for example, at two frequencies different from the frequency f₀. The receiving antenna is properly decoupled from the MRI device, A.

When receiving, when the switch INT is open, i.e. when it is no longer supplied with current, the receiving antenna B_REC behaves as a circuit comprising the matching capacitor C_{M} in series with the receiving coil B_{R} mounted in series with the tuning capacitor C_{T}, i.e. as a circuit LC resonating at the frequency f₀. The receiving transmission line LTR behaves like a transmission line matched in impedance with the receiving antenna B_REC. The receiving antenna B_REC is then coupled with the MRI device, A. It receives and transmits to the receiver the RF signals arising from the excitation of the area to be imaged.

The embodiment of FIG. 2 comprises a single transmission line LTR for performing the function of transmitting RF signals and decoupling. It is particularly compact and has a good signal to noise ratio.

A drawback of this embodiment lies in the limited, potentially insufficient efficiency of the decoupling, which results in artifacts on the images, and in spatial variations of the effective tilt angle of the MRI sequence used and therefore in an unwanted change in contrasts and associated degradation of the diagnosis. The quality factor of the decoupling circuit CD1 is inversely proportional to the resistance of the decoupling circuit CD1. The resistance of the decoupling circuit CD1 is equal to the sum of the resistance of the matching capacitor C_{M}, the resistance of the receiving transmission line LTR, the resistance of the blocking capacitor C_{B}, the resistance of the switch INT. A drawback of the limited decoupling is the possibility of inducing local hot spots around the receiving antenna B_REC due to the circulation of non-negligible electrical currents in the receiving antenna during the transmission phase.

### Second Embodiment

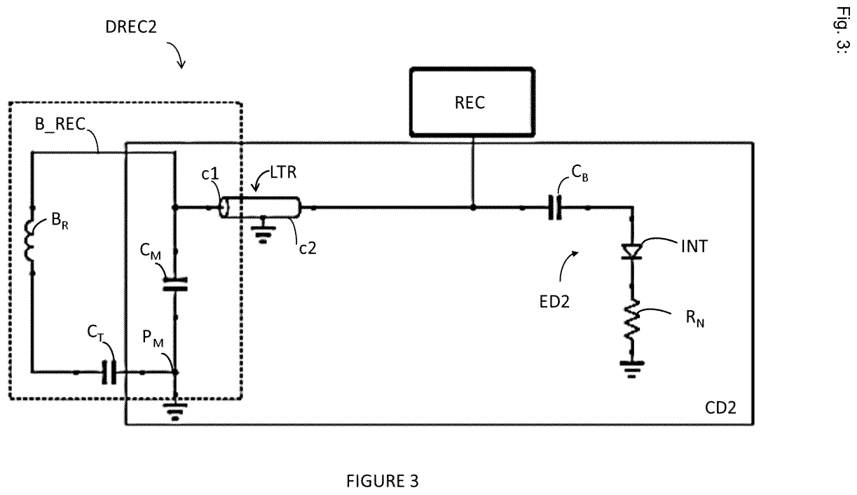

FIG. 3 shows an electrical diagram of a receiving device DREC2 according to a second embodiment of the invention.

This second embodiment differs from the first embodiment in that the decoupling equipment ED2 of the decoupling circuit CD2 comprises an electrical circuit R_{N} having a negative resistance mounted in series with the switch INT, i.e. with the first conductor c1 of the receiving transmission line LTR. An electrical circuit R_{N} with a negative resistance means an electrical circuit having a resistance, of which the ratio between the voltage at the terminals of the circuit R_{N} and the current flowing in the circuit R_{N} is negative. It behaves like a component having a resistance of value less than zero Ohms. This electrical circuit R_{N} is mounted in series with the switch INT.

An advantage of this solution is to have a more efficient decoupling than the embodiment of FIG. 2, because the decoupling circuit CD2 thus has a quality factor of the decoupling circuit higher than that of the decoupling circuit CD1 of FIG. 2. Indeed, the quality factor of the decoupling circuit CD2 is inversely proportional to the resistance of the decoupling circuit CD2. This makes it possible to limit artifacts on the generated images. Furthermore, this solution remains compact since no additional components are added to the part inserted into the human body.

In the transmission phase, the resistance of the decoupling circuit CD2 is equal to the sum of the resistance of the matching capacitor C_{M}, the resistance of the receiving transmission line LTR, the resistance of the blocking capacitor C_{B}, the resistance of the switch INT and the resistance of the circuit with negative resistance R_{N}. The negative resistance circuit therefore makes it possible to increase the quality factor of the decoupling circuit by reducing the total resistance of the decoupling circuit. The quality factor of the decoupling circuit is increased in the transmission phase. This therefore makes it possible to improve the decoupling efficiency between the receiving antenna and the transmitting antenna in the transmitting phase of the MRI/MRS device.

This solution is particularly advantageous for intracardiac applications where constraints on the maximum cable diameter are high. However, the smaller the diameter of the transmission line, the higher its resistance, which has the effect of generating losses in the receiving transmission line LTR.

Advantageously, the negative resistance circuit R_{N} is configured so that the resistance of the decoupling circuit CD2 is substantially zero.

In the non-limiting example of FIG. 3, the switch INT is connected to ground by the negative resistance circuit R_{N} mounted in series with the switch INT.

In an alternative, the negative resistance RN connects the transmission line to the blocking capacitor C_{B} or the blocking capacitor to the switch IN.

In the non-limiting example of FIG. 3, the cathode of a PIN diode is connected to ground by the negative resistance circuit R_{N} mounted in series with the switch INT.

In a manner known per se, the negative resistance circuit R_{N} may be made in different ways. It may comprise two cross-coupled metal oxide semiconductor field effect transistors, also called MOSFETs. In an alternative, the circuit RN may be made based on an operational amplifier, a tunnel effect diode, a programmable unijunction transistor also called PUT (acronym for “Programmable unijunction transistor”) or a Gunn diode.

The negative resistance electrical circuit R_{N} requires its own power supply which is not shown in FIG. 3. This power supply is advantageously connected to the negative resistance circuit by a power supply cable such that the power supply is located outside the human body when the receiving antenna is located in the heart.

Advantageously, as in the non-limiting example of FIG. 3, the negative resistance circuit is mounted so as to be intended to be outside the human body when the receiving antenna B_REC (or B_REC4) is inside the patient's heart. This solution does not require direct current, leakage of which may cause cardiac arrest, to be supplied inside the patient's heart.

Furthermore, this embodiment does not require the use of miniature elements for making the switch or the negative resistance circuit to be able to introduce them into the heart. This makes it possible to produce a simple and low cost device.

Furthermore, the fact that these elements are intended to be located outside the human body makes it possible to limit the number of elements of the part of the device intended to be introduced into the heart and therefore miniaturizing this part.

The invention also relates to an MRI/MRS system comprising the MRI/MRS device A as well as the receiving device DREC2 according to the alternative shown in FIG. 1. This is equivalent to replacing the decoupling equipment ED1 with the decoupling equipment ED2 in FIG. 1.

### Third Embodiment

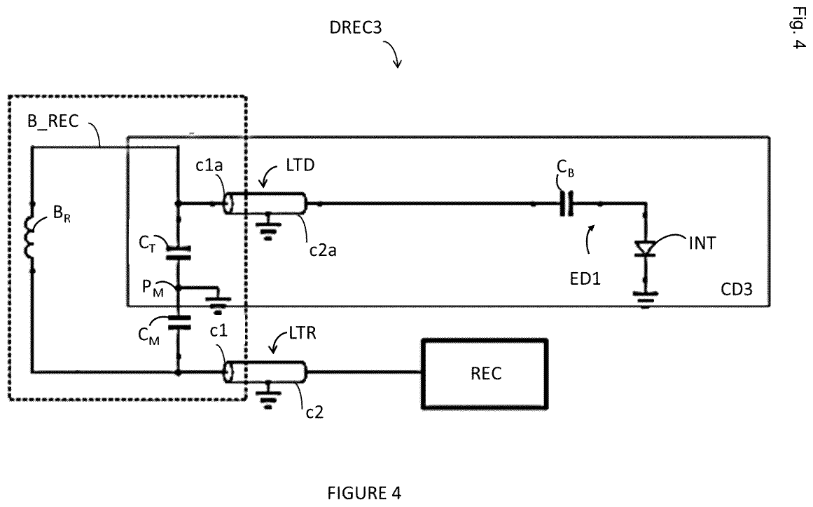

FIG. 4 shows an electrical diagram of a receiving device DREC3 according to a third embodiment of the invention. The receiving device DREC3 according to the third embodiment differs from that of the first embodiment in that it comprises a transmission line, so-called decoupling, LTD in addition to the receiving transmission line LTR.

The receiving transmission line LTR is intended to electrically connect the receiving antenna B_REC to the receiver REC.

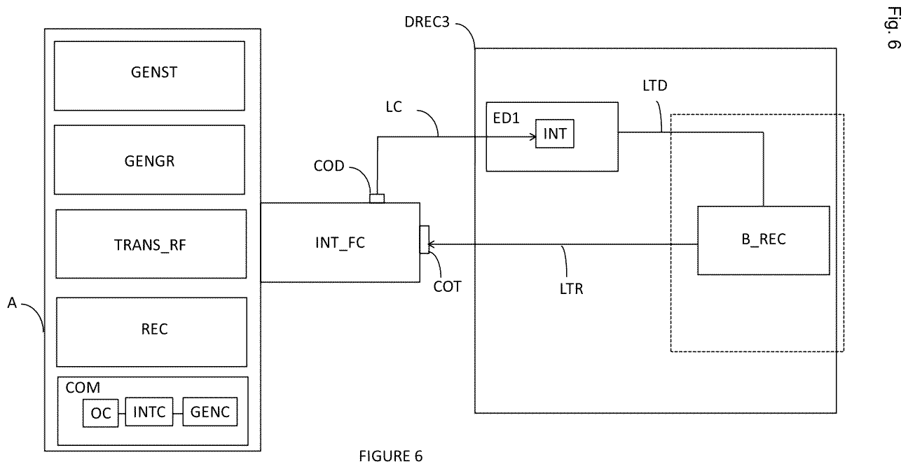

For this purpose, the receiving transmission line LTR is advantageously intended to electrically connect (or electrically connects) the transmission connector COT to the receiving antenna B_REC as shown in FIG. 6.

This connection is made without going through the switch INT.

The decoupling transmission line LTD, just like the receiving transmission line LTR, may be made in the form of a coaxial cable, a two-wire line or a twisted pair.

The decoupling transmission line LTD comprises a first conductor c1a comprising a proximal end intended to be electrically connected to the decoupling equipment ED1, as shown in FIG. 6, and a distal end electrically connected to the receiving antenna B_REC.

The decoupling transmission line LTD comprises a second conductor c2a electrically connected to ground.

The decoupling efficiency of this embodiment may be higher than that of the first embodiment which makes it possible to limit artifacts on the images. This makes it a good solution when space constraints can accommodate the presence of two cables. This solution is simple to implement because it implies limited constraints on the geometry and the configuration of the receiving transmission line LTR, only the decoupling transmission line LTD participating in the decoupling being constrained.

In the particular embodiment of FIG. 4, the distal end of the first conductor c1a of the decoupling transmission line LTD is electrically connected to the receiving antenna B_REC at the first terminal of the tuning capacitor C_{T}, the second terminal of the tuning capacitor C_{T} being connected to the ground point P_{M}. The receiver REC is intended to be electrically connected to the receiving transmission line LTR without being connected to the decoupling transmission line LTD so as to receive radio frequency signals received by the receiving antenna B_REC via the receiving transmission line LTR without passing through the decoupling transmission line LTD.

Put another way, the receiver REC is intended to be electrically connected to the receiving transmission line LTR so as to be intended to receive radio frequency signals received by the receiving antenna B_REC via the receiving transmission line LTR without these signals passing through the decoupling transmission line LTD.

In other words, the receiver REC is intended to be electrically connected to the receiving antenna B_REC via the receiving transmission line LTR without passing through the decoupling transmission line LTD.

The conductor c1 advantageously comprises a first end electrically connected to the receiving antenna B_REC and a second end intended to be electrically connected to the receiver REC.

This connection is made, for example, via a transmission connector COT.

In addition, the switch INT is electrically connected to the receiving antenna via the decoupling transmission line LTD without passing through the receiving transmission line LTR.

Put another way, two separate transmission lines are used to ensure:
during the transmission phase, the decoupling between the receiving antenna and the transmitting antenna of the MRI/MRS device,
during the receiving phase, transmitting to the receiver REC, signals coming from the receiving antenna which are intended to be received by the receiver REC.

In other words, among the decoupling functions of the receiving antenna during the transmission phase and transmission during the receiving phase, the decoupling transmission line LTD participates only in the decoupling and the receiving transmission line LTR participates only in the transmission. Transmission means transmission from the receiving antenna to the receiver of signals intended to be received by the receiver.

Thus, the decoupling circuit CD3, surrounded by a full line frame in FIG. 4, differs from that of the first embodiment in that it comprises the decoupling transmission line LTD, the tuning capacitor C_{T} and the decoupling equipment ED1.

To have the decoupling function, the decoupling transmission line LTD has an inductance function. The length of the decoupling transmission line LTD is defined so that the resonance frequency of the decoupling circuit CD3 is equal to the frequency f₀. This length is calculated approximately, and the precise length is then determined experimentally so as to obtain the desired resonance frequency. This length constraint does not apply to the receiving transmission line LTR in this embodiment.

This embodiment makes it possible, by separating the functions of the two transmission lines, to improve both the decoupling quality by adjusting the length of the decoupling transmission line LTD and the capacitance of the tuning capacitor C_{T} and the receiving quality by matching the impedance of the receiving antenna B_REC to that of the receiving transmission line LTR at the working frequency f₀ of the MRI/MRS device.

Thus, advantageously, the length of the decoupling transmission line LTD is defined such that the resonance frequency of the decoupling circuit CD3 is equal to the frequency f₀ and such that the impedance of the receiving antenna B_REC is matched to that of the receiving transmission line B_REC at the working frequency f₀ of the MRI/MRS device.

In other words, the equivalent impedance of the receiving antenna B_REC is defined so as to be seen, by the receiving transmission line LTR, as an impedance equal to the characteristic impedance of the receiving transmission line LTR at the working frequency f₀ of the MRI/MRS device.

The characteristic impedance of the receiving transmission line LTR at the frequency f₀ is, for example, 50 Ohms.

Together, this technical solution makes it possible:
to optimize the quality of the decoupling, positioned remotely outside the human body, of the receiving antenna during the transmission phase to avoid degradation of the quality of the measured signals and to ensure the safety of the patient (absence of radio frequency currents circulating in the receiving antenna during the transmission phase and absence of electrically supplied components inside the human body),
to optimize the transmission of the signal to the receiver REC during the receiving phase to maximize the signal to noise ratio of the signals measured by the receiving antenna.

The separation of the two circuits offers additional flexibility in the selection of electronic components, allowing each function to be optimized independently (decoupling in the transmission and receiving phases of the signal). This selection is advantageously made by taking into account the space constraints related to the introduction of the receiving antenna into the heart, and notably the losses generated by cables having a small diameter.

The length of the decoupling transmission line LTD is defined such that the decoupling equipment and more particularly the switch INT is located outside the human body when the receiving antenna B_REC is located in the heart.

It is typically greater than or equal to 30 cm or 40 cm when the receiving antenna is intended to be inserted into the body through a jugular access and greater than or equal to 80 cm when the receiving antenna is intended to be inserted into the body through an access via the groin.

### Alternative of the Third Embodiment

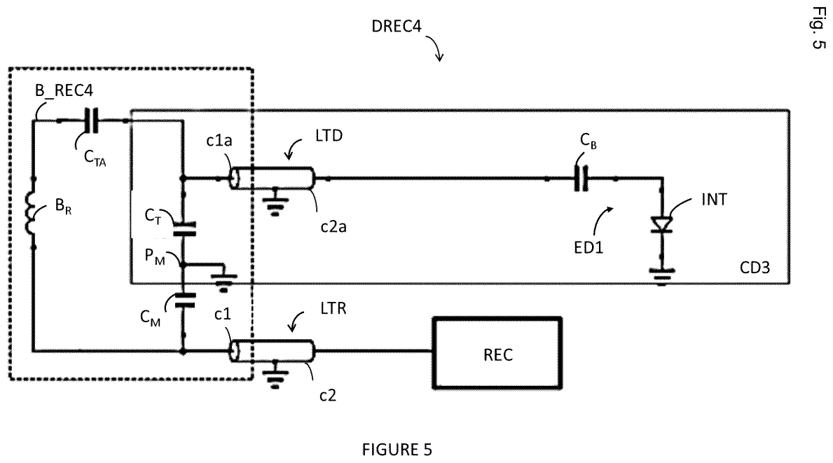

FIG. 5 shows an alternative of the third embodiment which differs from that of FIG. 4 in that the receiving antenna B_REC4 of the receiving device DREC4 comprises an additional turning capacitor C_{TA} connected in series with the capacitors C_{M} and C_{T}. The additional tuning capacitor C_{TA} is connected to the tuning capacitor C_{T} at the first terminal of the tuning capacitor C_{T}. This feature makes it possible to choose another value for the length of the decoupling transmission line LTD if necessary, or to have another value for the capacitance of the tuning capacitor C_{T} if ever there are constraints to use certain values.

It should be noted that, in the third embodiment, as well as in its alternative, the decoupling equipment of the decoupling circuit may comprise an electrical circuit R_{N} having a negative resistance mounted in series with the switch INT, i.e. with the first conductor c1 of the decoupling transmission line LTD, as in the second embodiment. The different assemblies, dispositions and embodiments of the negative resistance described with reference to FIG. 3 are applicable to the third embodiment and its alternative.

The invention also relates to an MRI/MRS system comprising the MRI/MRS device A as well as the receiving device DREC4 according to the alternative shown in FIG. 5. This is equivalent to replacing the receiving antenna B_REC with the receiving antenna B_REC4 in FIG. 6.

### Other Features

To prevent heating of the cables (transmission lines) inserted into the sheath, it is possible to distribute circuits LC also called traps along at least one of the transmission lines (LTR and/or LTD) to prevent the circulation of parasitic currents as described in the aforementioned article.

In the embodiments shown in the figures, the matching capacitor is mounted in series with the tuning capacitor(s). In an alternative, the receiving antenna comprises, in place of this matching capacitor and/or in addition, a matching capacitor or a matching capacitor network mounted in series with the transmission line mounted in series with the decoupling equipment.

### Sheathed Receiving Device

Advantageously, the receiving device comprises a tubular sheath made of electrically insulating material.

The sheath is flexible so as to be potentially mechanically deflected.

The sheath is advantageously in the form of an elongated tube along an axis of the sheath capable of having a maximum (outer) diameter substantially constant over its entire length or over the entire length of its part intended to be introduced into the human body.

This outer diameter is compatible with the maximum dimensions of the vessels into which it is to be inserted.

Advantageously, this diameter is less than 2 mm.

The tubular sheath delimits an elongated inner lumen along the x axis and receiving the control line LC, the receiving transmission line LTR and the possible decoupling transmission line LTD.

The sheath comprises a proximal end and is mechanically connected to the switch INT or, more generally, to the decoupling equipment and a distal end capable of receiving the receiving resonant antenna B_REC or B_REC4.

The distal end of the sheath is intended to be introduced into the human body and more particularly into a vessel connected to the heart and the proximal end of the sheath is intended to remain outside the human body.

Advantageously, the receiving antenna is capable of being in a deployed state in which it has a diameter greater than that of the sheath in the axis of the sheath. The receiving antenna is then received in the sheath when it is in a folded state.

The receiving antenna may, for example, be integrated with an inflatable/deflatable balloon inside the heart cavity, or include a mechanical system allowing it to deploy in contact with the area to be imaged and to fold it to maneuver it into blood vessels connected to the heart, or any other system allowing its geometry to be modified between the phase of insertion/removal of the sheath from the human body and the imaging phase.

1. A receiving device for receiving radio frequency signals for a magnetic resonance imaging or spectroscopy system comprising an intracardiac receiving resonant antenna and a switch capable of being alternately in an open state when the switch is supplied by a direct current having a first intensity such that the intracardiac receiving resonant antenna is tuned to an operating frequency of the magnetic resonance imaging or spectroscopy system and in a closed state when the switch is supplied by a direct current having a second intensity such that the frequency of the intracardiac receiving resonant antenna is detuned, the intracardiac receiving resonant antenna being further configured to be connected to a receiver configured to receive the radio frequency signals received by the intracardiac receiving resonant antenna when the switch is in the open state, the receiving device further comprising a first transmission line (LTR, LTD) having a conductor having a distal end electrically connected to the intracardiac receiving resonant antenna and a proximal end electrically connected to the switch such that the switch is configured to be located outside the human body when the intracardiac receiving resonant antenna is located inside a patient's heart.

2. The receiving device according to claim 1, comprising, in addition to the first transmission line, a second transmission line having a conductor comprising a distal end electrically connected to the intracardiac receiving resonant antenna and a proximal end configured to be electrically connected to the receiver to transmit to the receiver the radio frequency signals received by the intracardiac receiving resonant antenna.

3. The receiving device according to claim 2, wherein the receiver is configured to be electrically connected to the receiving transmission line so as to receive radio frequency signals received by the intracardiac receiving resonant antenna via the receiving transmission line without passing through the decoupling transmission line.

4. The receiving device according to claim 3, wherein the intracardiac receiving resonant antenna comprises a tuning capacitor and a matching capacitor mounted in series and connected by a ground point, the matching capacitor electrically connecting the conductor of the second transmission line to the ground point.

5. The receiving device according to claim 1, wherein the proximal end of the conductor of the first transmission line is configured to be connected to the receiver to transmit to the receiver the radio frequency signals received by the intracardiac receiving resonant antenna.

6. The receiving device according to claim 4, wherein the intracardiac receiving resonant antenna comprises a matching capacitor electrically connecting a ground point to the conductor of the first transmission line.

7. The receiving device according to claim 1, comprising an electrical circuit having a negative resistance mounted in series with the switch.

8. The receiving device according to claim 7, wherein the electrical circuit having the negative resistance connects the switch to ground.

9. The receiving device according to claim 7, wherein the electrical circuit having the negative resistance is intended to be located outside the human body when the receiving antenna is located inside a patient's heart.

10. The receiving device according to claim 1, comprising a sheath receiving the first transmission line, the sheath comprising a proximal end mechanically connected to the switch and a distal end capable of receiving the intracardiac receiving resonant antenna.

11. The receiving device according to claim 9, wherein the sheath has a diameter less than or equal to 2 mm.

12. A magnetic resonance imaging or spectroscopy system comprising a receiving device according to claim 1, a magnetic resonance imaging or spectroscopy device, the magnetic resonance imaging or spectroscopy device comprising a main magnet configured to generate a static magnetic field, a gradient generator comprising gradient coils and a transmission antenna configured to transmit radio frequency signals.

13. The imaging resonance imaging or spectroscopy system according to claim 11, wherein the magnetic resonance imaging or spectroscopy device comprises the receiver.
